(19) United States
(12) Patent Application Publication
(10) Pub. No.: US 2026/0040874 A1
(43) Pub. Date: Feb. 5, 2026

(54) METHOD AND PROCESSING CHAMBER FOR REDUCING WARPAGE OF A SUBSTRATE

(71) Applicant: Applied Materials, Inc., Santa Clara, CA (US)

(72) Inventors: Christian GRONET, Santa Clara, CA (US); Brian BURROWS, San Jose, CA (US); David Masayuki ISHIKAWA, Mountain View, CA (US); Kelvin CHAN, San Ramon, CA (US)

(21) Appl. No.: 18/792,489

(22) Filed: Aug. 1, 2024

(51) Int. Cl. H01L 21/67

(52) U.S. Cl. CPC H01L 21/67288; H01L 21/67115; H01L 21/67248

(57) ABSTRACT

Disclosed herein are a warpage control method and system for warpage control included in a processing chamber. The warpage control method includes heating a substrate by a heating assembly comprising a plurality of independently controllable heating zones, measuring a backside temperature of a susceptor based on radiation at a first wavelength, measuring a topside temperature of the substrate based on radiation at a second wavelength, measuring a curvature of the substrate based on radiation at a third wavelength, and controlling the heating assembly based on the backside temperature, the topside temperature, and the curvature. The warpage control system includes a first thermal sensor and an warp sensor disposed above a substrate, a second thermal sensor disposed below the substrate, a heating assembly, and a controller coupled with the heating assembly, the first thermal sensor, the second thermal sensor, and the warp sensor for controlling the warpage of the substrate.

### BACKGROUND

### Field

The present disclosure relates to a processing chamber and method for reducing warpage of a substrate during processing, and, more specifically, relates to a processing chamber and method for reducing warpage of a SiC substrate.

### Description of the Related Art

In semiconductor manufacturing, a substrate is often supported by a susceptor and then heated to an elevated temperature for etch, deposition, and other processes. The substrate is often rotated by the susceptor to obtain a uniform processing result. Warpage often occurs in a substrate due to temperature gradients causing by uneven heating, structural difference across a substrate, pre-existing stress, defects, or other factors. Warpage of a rotating substrate can cause that substrate to be dislodged from the pocket of a carrying susceptor. In addition, process gases can also enter spaces exposed by the warpage, such as a backside of the substrate, causing deposition or etch of materials at undesired locations of a substrate.

A silicon carbide (SiC) substrate is particularly prone to warpage during processing. For example, a SiC substrate tends to be highly stressed and can warp easily. A SiC substrate is also processed at a relatively high temperature, such as 1,500° C. to 1,800° C. or an even higher temperature. To reduce the processing cycle, a high heating or cooling rate is also used for processing a SiC substrate. The high heating or cooling rate exacerbates the warpage of the substrate because the high heating or cooling rate leaves little time for the SiC substrate to ease any temperature gradient.

Thus, a need exists for an improved method and processing chamber to control the warpage of a SiC substrate during an epitaxial growth of SiC.

### SUMMARY

Disclosed herein are a warpage control method and system of a substrate processing chamber. In an example, the warpage control method includes heating a substrate by a heating assembly comprising a plurality of independently controllable heating zones, measuring a backside temperature of a susceptor based on radiation at a first wavelength, measuring a topside temperature of the susceptor based on radiation at a second wavelength, measuring a warpage of the substrate based on radiation at a third wavelength, and controlling the heating assembly based on the backside temperature, the topside temperature, and/or the warpage.

In another example, a warpage control system includes a heating assembly including a plurality of heating lamps, a first thermal sensor including a tube penetrating the heating assembly and configured to measure radiation at a first wavelength, a second thermal sensor disposed above the heating assembly and the first thermal sensor and configured to measure radiation at a second wavelength, a warp sensor disposed above the heating assembly and configured to measure radiation at a third wavelength, and a controller coupled with the heating assembly, the first thermal sensor, the second thermal sensor, and the warp sensor.

In another example, a substrate processing chamber includes a susceptor configured to support a substrate, an edge ring configured to support a susceptor, the susceptor being detachable from the edge ring; and the warpage control system as set forth in various embodiments of the present disclosure.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 illustrates a schematic top view of a processing system, according to an embodiment of the present disclosure.

FIG. 2 illustrates a schematic cross-sectional view of a deposition chamber, according to an embodiment of the present disclosure.

FIG. 3 illustrates a perspective cross-sectional view of a heating assembly, according to an embodiment of the present disclosure.

FIG. 4 illustrates a schematic cross-sectional view of a heating assembly, according to an embodiment of the present disclosure.

FIG. 5 illustrates a schematic configuration of a warp sensor, according to an embodiment of the present disclosure.

FIG. 6 illustrates a method for controlling the warpage of a substrate, according to an embodiment of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The disclosure contemplates that terms such as “couples,” “coupling,” “couple,” and “coupled” may include but are not limited to welding, fusing, melting together, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links, blocks, and/or frames.

Disclosed herein are a processing chamber and method for controlling warpage of a substrate during processing. The processing chamber utilizes a thin susceptor for carrying a substrate. The processing chamber also has a close-loop controlling system which couples a controller with a heating assembly, a plurality of topside thermal sensors, a plurality of backside thermal sensors, and a plurality of topside warp sensors. The heating assembly is positioned at a backside of a substrate and has a plurality of heating zones that can be independently controlled. The controller controls the heating assembly based on the temperatures measured by the thermal sensors and the curvature measured by the warp sensors.

The backside thermal sensors are used for controlling the heating assembly during a temperature ramping-up process to heat up the temperature of a substrate. The backside thermal sensors are configured to measure the backside temperature of the susceptor at a first wavelength, such as about 5.2 μm, which is less interfered by heating lamps in the heating assembly. The topside thermal sensors are used for controlling the heating assembly during deposition. To more accurately measure the temperature, the topside thermal sensors have an emissivity-correction system that accounts for the emissivity change due to the deposited materials, as well as characteristics of each substrate. The topside thermal sensors may measure the topside temperature of the substrate at a second wavelength that is shorter than that of the backside thermal sensors. A shorter wavelength provides stronger signals due to temperature changes than a longer wavelength.

A deposition cycle may be divided into three processes: a pre-deposition process, a deposition process, and a cooling process. During the pre-deposition process, the controller may first rely on the backside temperature and the warp sensor to heat up the substrate to a first temperature, which is lower than a deposition temperature. The substrate may also be rotated at a slower speed than a deposition speed. While the first temperature is maintained, the controller controls the heating assembly according to a temperature profile to reduce the warpage of the substrate. When the warp sensor indicates a minimized warpage profile is achieved, the substrate is heated to the deposition temperature, and the rotational speed is increased to the deposition speed. Then, the controller switches to the topside temperature for controlling the deposition process. During the cooling down process, either the backside temperature or the topside temperature or both may be used for controlling.

A processing chamber having a warpage control system as set forth in the present disclosure can reduce the incidence that a substrate flies out of a susceptor even when both the heating rate and rotational speed are very high. As a result, the number of damaged substrates is reduced, and the throughput of a processing chamber is increased. The substrate can also have an improved uniformity in the processing result and reduce deposition or etch at unwanted areas or locations of a substrate.

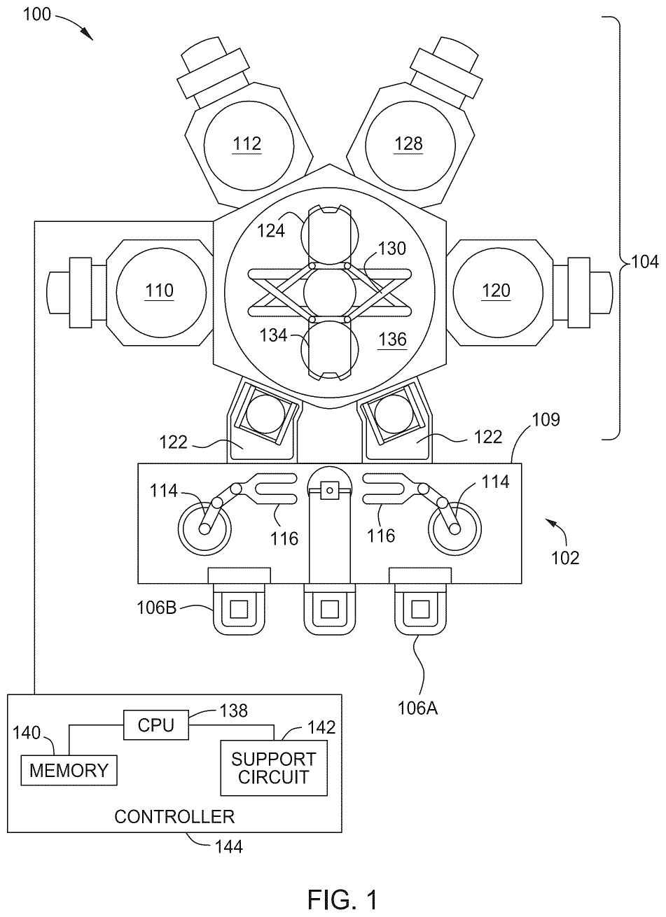

FIG. 1 illustrates a schematic top view of a processing system 100, according to one or more embodiments. According to an embodiment, the processing system 100 includes a processing chamber having a warpage control system as set forth in various embodiment of the present application. The processing system 100 includes one or more load lock chambers 122 (two are shown in FIG. 1), a processing platform 104, a factory interface 102, and a controller 144. In one or more embodiments, the processing system 100 may be adapted for use in a CENTURA® integrated processing system provided by Applied Materials, Inc., located in Santa Clara, California. It is contemplated that other processing systems (including those from other manufacturers) may be adapted to benefit from the present disclosure.

The processing platform 104 includes a plurality of processing chambers 110, 112, 120, 128, and a transfer chamber 136. The plurality of processing chambers 110, 112, 120, 128 may include an atomic layer deposition (ALD) chamber, an epitaxy deposition (EPI) chamber, a physical vapor deposition (PVD) chamber, a chemical vapor deposition (CVD) chamber, a molecular beam epitaxy (MBE) chamber, an etch chamber, a rapid thermal processing (RTP) chamber, or any other substrate processing chamber. In an embodiment, the plurality of processing chamber 110, 112, 120, 128 include an EPI chamber configured to process a silicon carbide (SiC) substrate at a temperature range of at least 1,000° C., at least 1,200° C., at least 1,400° C., or at least 1,800° C.

Each of the processing chambers 110, 112, 120, 128 is coupled to the transfer chamber 136. The transfer chamber 136 can be maintained under vacuum. The factory interface 102 is coupled to the transfer chamber 136 through the load lock chambers 122. Two load lock chambers 122 are shown in FIG. 1. The load lock chambers 122 are used to transfer substrates from an ambient (e.g., atmospheric) pressure environment of the factory interface 102 to the vacuum environment of the transfer chamber 136.

In one or more embodiments, the factory interface 102 includes at least one docking station 109 and at least one factory interface robot 114 to facilitate the transfer of substrates 124. The docking station 109 is configured to accept one or more front opening unified pods (FOUPs). Two FOUPS 106A, 106B are shown in the implementation of FIG. 1. The factory interface robot 114 has a blade 116 that is configured to transfer one or more substrates from the FOUPS 106A to the load lock chambers 122.

Each of the load lock chambers 122 has a first port interfacing with the factory interface 102 and a second port interfacing with the transfer chamber 136. The transfer chamber 136 has a vacuum robot 130 disposed therein. The vacuum robot 130 has one or more blades 134 (two are shown in FIG. 1) capable of transferring the substrates 124 between the load lock chambers 122 and the processing chambers 110, 112, 120, and 128.

The controller 144 is coupled to the processing system 100 and is used to control processes and methods, such as the operations of the methods described herein (for example the operations of the methods as described in other parts of the present disclosure). The controller 144 includes at least one central processing unit (CPU) 138, a non-transitory computer readable medium (e.g. a memory) 140 containing instructions executed by the CPU 138, and support circuits 142 for the CPU. The controller 144 controls various items directly, or via other computers and/or controllers.

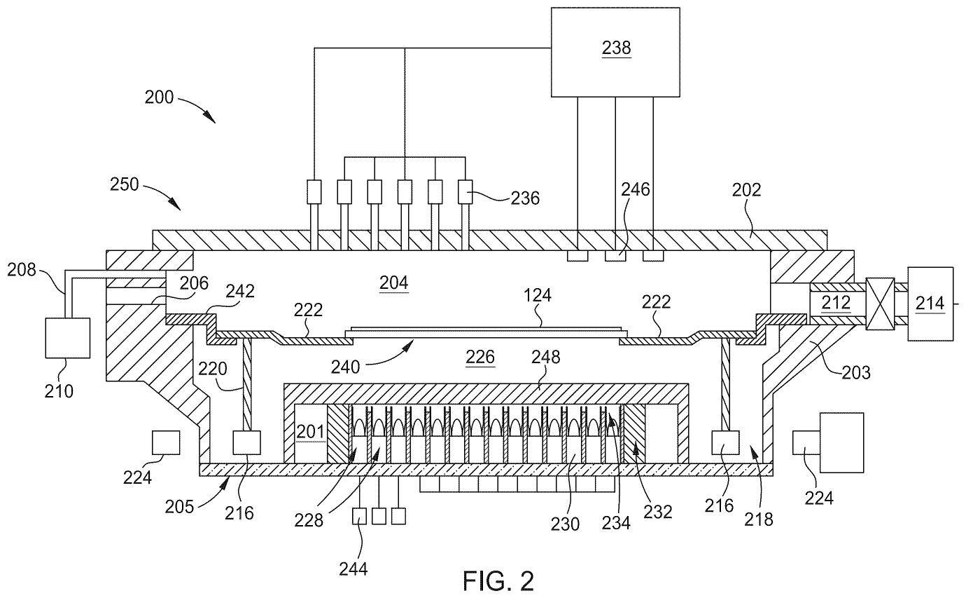

FIG. 2 illustrates a schematic cross-sectional view of a processing chamber 200 having a warpage control system, according to an embodiment of the present disclosure. The processing chamber 200 can be one or more of the processing chambers 110, 112, 120, and 128 as shown in FIG. 1. In an embodiment, the processing chamber 200 functions as an epitaxy deposition chamber configured to deposit one or more layers of materials on a substrate 124. In another embodiment, the processing chamber 200 functions as a RTP chamber. The processing chamber 200 includes a controller 238 coupled with other components of the processing chamber and configured to operate the various components and processing operations of the processing chamber 200.

The processing chamber 200 includes a chamber body 250 having a top section 202, a side section 203 and a bottom section 205, which enclose a processing volume 204 configured for processing the substrate 124. The chamber body 250 may be made of stainless steel with a liner. A slit valve 206 may be formed on the side section 203 for providing a passage for the substrate 124 to be transferred in and out of the processing chamber 200. A gas inlet 208 may be connected to a gas source 210 to provide process gases, such as source gases, purge gases, carrier gases, and/or cleaning gases, to the processing volume 204. In an embodiment, the substrate 124 includes a SiC substrate. The processing chamber 200 is configured to deposit a SiC film on the substrate 124. The source gases for depositing a SiC film may include a silicon (Si) source gas, a carbon source gas, an additive gas, or any other suitable gas. The Si source gas may include monosilane, dichlorosilane, trichlorosilane, silicone tetrachloride, or any other suitable Si source gas. The carbon source gas may include propane, acetylene, ethylene, or any other suitable carbon source gas. The additive gas may include a hydrogen chloride gas or a dopant gas. The carrier gas may include a hydrogen (H2) gas or an inert gas, such as helium, argon, or other inert gas. The purge gas may include a hydrogen gas or an inert gas, helium, argon, or other inert gas. The vacuum pump 214 may be fluidly connected to the processing volume 204 through an outlet 212 for pumping out effluent gases.

The substrate 124 is supported by a susceptor 240. The susceptor 240 may be made of any suitable material, such as SiC, graphite coated with SiC, or other material. The susceptor 240 may also be very thin, such as no greater than 2 mm, or no greater than 1.5 mm, or no greater than 1.0 mm, for fast thermal exchange. The susceptor 240 is supported by an edge ring 222 disposed on a tubular member 220. The susceptor 204 is also detachable from the edge ring 222 such that the susceptor 204 and the substrate 124 may be removed from the processing chamber 200 altogether. An outer ring 242 covers a gap between the side section 203 and the edge ring 222. The tubular member 220 rests on or otherwise coupled to a magnetic rotor 216. The magnetic rotor 216 is disposed in the circular channel 218. A magnetic stator 224 is located externally of the magnetic rotor 216 and is magnetically coupled through the side section 203 to induce rotation of the magnetic rotor 216 and hence of the edge ring 222 and the substrate 124 supported thereon. The magnetic stator 224 may be also configured to adjust the elevations of the magnetic rotor 216, thus lifting up or lowering down the substrate 124.

In the processing volume 204, a heating assembly 201 is disposed below (backside) the substrate 124 and includes a plurality of heating elements 228. The heating elements 228 may be UV lamps, halogen lamps, laser diodes, resistive heaters, microwave powered heaters, light emitting diodes (LEDs), or any other suitable heating elements both singly or in combination. The heating elements 228 may be disposed in reflector pockets 230 formed in a reflector base 232. Cooling channels 234 are formed in the reflector base 232. In one embodiment, the heating elements 228 may be divided into a plurality of heating groups to heat the substrate 124. Each heating group may be controlled independently by the controller 238 to provide desired temperature profile across a radius of the substrate 124. A coolant, such as water, may be circulated inside the cooling channels 234. An optional transparent window 248 may be disposed between the heating assembly 201 and the susceptor 240.

A protective region 226 is formed between the heating assembly 201 and the susceptor 240 and is configured to protect components disposed between the susceptor 240 and the bottom section 205, such as the backside of the susceptor 240 and the heating assembly 201. In an embodiment, the protective region 226 is filled with a purge gas, such as helium, to prevent process gases in the processing volume 204 from reaching the backside of the susceptor 240 and the heating assembly 201, thus preventing deposition on these components. The processing volume 204 and the protective region 226 may have different environments, such as different gases, different gas pressures, and different temperatures. In an embodiment, the pressure of the protective region 226 is higher than the processing volume 204. The protective region 226 is separated from the processing volume 204 by the susceptor 240, the edge ring 222, and the outer ring 242.

In an embodiment, the protective region 226 is configured to reduce any unnecessary loss of radiation emitted by the heating assembly 201. For example, the protective region 226 is very thin, such as no thicker than 10 mm, or no thicker than 5 mm, or even thinner. In another example, only gases are disposed in the protective region 226. No other intervening parts or components are disposed in the protective region 226 that could interfere with the radiation emitted by the heating assembly 201. A traditional processing chamber may include a transparent window disposed between the susceptor 240 and the heating assembly 201 for protection. The processing chamber 200 of the present disclosure includes no such transparent or protective window in the protective region 226, according to an embodiment. Instead, a purge gas is used for protecting the heating assembly 201. By disposing the front side of the heating assembly 201 and the back side of the susceptor 240 in the same protective region 226 and arranging them to face each other directly, radiation emitted by the heating assembly can reach the susceptor 240 directly, only subject to any interference with the purge gas that may fill the protective region 226.

In an embodiment, a plurality of backside thermal sensors 244 may be disposed below the substrate 124 and the susceptor 240. The backside thermal sensors 244 are configured to measure temperatures at a backside of the susceptor by measuring a blackbody emission of the susceptor at a first wavelength. In an embodiment, to improve temperature accuracy and to increase light absorption from the lamps, the backside of the susceptor has surface treatments to increase the emissivity of the susceptor, such as increase the emissivity close to 1.0. The surface treatments may include laser patterning or oxidation, such as an oxide layer grown thermally on the surface of the susceptor. A plurality of topside thermal sensors 236 may be disposed above the substrate 124 and measure temperatures at a topside of the substrate 124. The topside thermal sensors 236 are configured to measure temperatures by measuring a blackbody emission of the substrate 124 at a second wavelength. In an embodiment, the first wave length is longer than the second wavelength. In an example, the first wavelength is at least about 3 μm, such as about 5.2 μm. The second wavelength is between about 500 nm and about 3 μm. The topside thermal sensors 236 and the backside thermal sensors 244 are capable of measuring temperatures at a high frequency, such as at least 30 Hz, or at least 60 Hz, or at an even higher frequency.

The processing chamber 200 may also include one or more warp sensors 246. A plurality of warp sensors 246, such as three (3) are shown disposed above the substrate 124 in FIG. 2. The warp sensors 246 are pointed to different locations of the substrate 124 and configured to measure a warpage of the substrate 124. The warpage may include a curvature, a tilt angle, a height, or any other suitable geometrical property of the substrate. In an embodiment, the warp sensors 246 may be combined with the topside thermal sensor 236. The warp sensor 246 is configured to measure the warpage by emitting a light at a third wavelength. The third wavelength may be between 500 nm and about 3 μm.

The controller 238 is coupled with the thermal sensors 236, 244 and the warp sensors 246. In an embodiment, the controller 238 controls the heating assembly 201 according to signals provided by the thermal sensors 236, 244, and the warp sensors 246. The controller 238 also controls a rotation speed of the susceptor 240 and the substrate 124. The controller 238 may also control other components of the processing chamber 200, such as the pump 214, the gas source 210, and other components. In an embodiment, the controller 238, the topside thermal sensors 236, the warp sensors 246, the backside thermal sensors 244, and the heating assembly 201 form part of a warpage control system of the processing chamber 200.

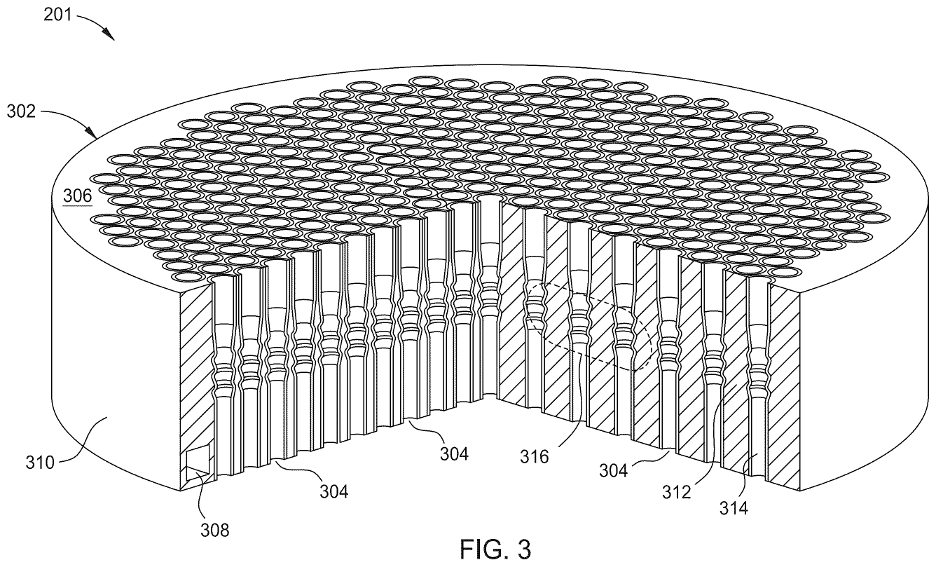

FIG. 3 illustrates a schematic perspective and cross-sectional view of the heating assembly 201, according to an embodiment of the present disclosure. The heating assembly 201 includes a base 302 and a plurality of reflector pockets 304 formed in the base 302. In an embodiment, the base 302 has a cylindrical shape formed by a front wall 306, a back wall 308, and a side wall 310. The front wall 306 defines a top or front surface of the base 302 and faces the susceptor 240. The back wall 308 defines a bottom surface of the base 302. The side wall 310 extends between the front wall 306 and the back wall 308.

The plurality of reflector pockets 304 are configured to receive a heat element 228 (shown in FIG. 2), such as a radiation lamp. Each reflector pocket includes a reflector configured to reflect radiation emitted by the heating element toward the front wall 306 and/or the susceptor 240 disposed above the front wall 306. Each reflector pocket 304 is cooled by a liquid coolant, such as water. In an embodiment, a gaseous coolant, such as helium, may also be flowed through the reflector pocket for cooling.

The base 302 includes a reflector cooling chamber 312 and a base cooling chamber 314. The reflector cooling chamber 312 is disposed around the reflector and is configured to cool the reflector. The base cooling chamber 314 is disposed under the reflector cooling chamber 312 and is configured to cool a coupling portion between the reflector pocket and a heating element.

The heating assembly 201 may include a structure made by an additive manufacturing process, such as a 3D printing process. With an additive manufacturing process, the heating assembly 201 can have complex shapes, such as a Fresnel shape 316 for the reflector. The shapes can also be very thin, such as no greater than 1 mm thick. The structure made by the additive manufacturing process can be subsequently polished and coated by layers of protective materials and/or layers of reflective materials. The structure made by the additive manufacturing process may be made of nickel, a nickel-containing supper alloy (such as Inconel), stainless steel, copper, and any other suitable material.

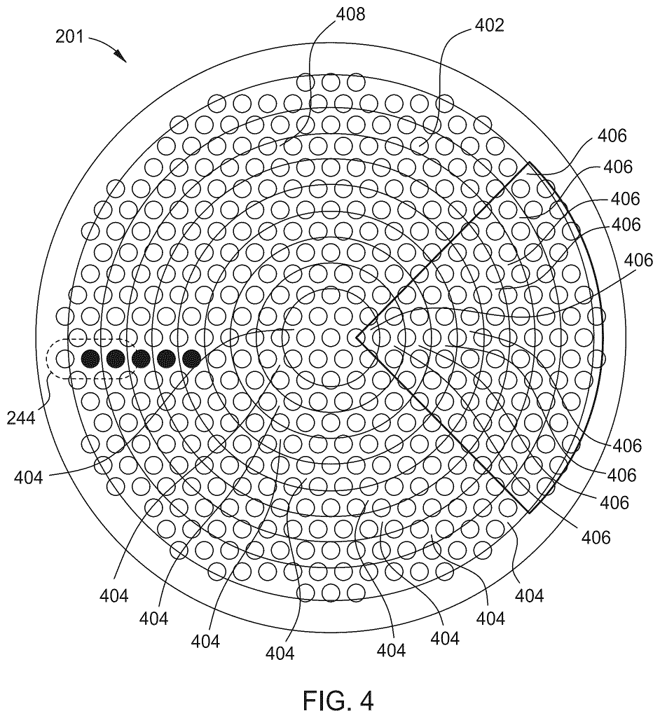

FIG. 4 illustrates a schematic top view of a heating assembly 201, according to an embodiment of the present disclosure. The heating elements 402 of the heating assembly 201 may be divided into a plurality of heating zones 408, whose heating power can be independently controlled. For example, the heating zones 408 include a plurality of annular bands, which are concentric to one another. Each annular band may be divided into two heating zones 404 and 406, which are complementary circular sectors. The heating zones 404 include a plurality of heating elements 402 and may have a circular angle greater than 180 degrees. In an example, the heating zones 404 are configured to be constantly supplied with a power signal for heating. The heating zones 406 also include a plurality of heating elements 402 and may have a circular angle less than 180 degrees. The heating zones 406 may configured to be intermittently supplied with a power signal for heating. Each of the heating zones 404, 406 can be independently controlled such that local areas of the substrate corresponding to the heating zones 404, 406 can have their temperatures independently adjusted. As a result, the uniformity of temperature on a substrate can be better controlled. As shown in FIG. 4, a plurality (5 are shown) of backside thermal sensors 244 are also disposed within the heating assembly 201.

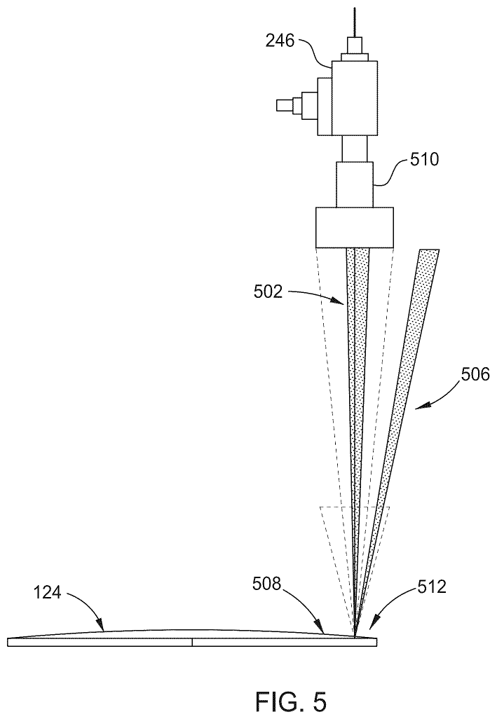

FIG. 5 illustrates a schematic configuration of a warp sensor 246, according to an embodiment of the present disclosure. The warp sensor 246 is capable of measuring a curvature ranging from −10,000 km⁻¹ (convex) to +1,000 km⁻¹ (concave). The warp sensor 246 includes a transceiver head 510 which has a laser emitters and a photodetector. In an embodiment, a laser emitter of the transceiver head 510 emits a laser beam 502 toward a front surface 508 of the substrate 124. The transceiver head 510 may also scan the laser beam 502 across the surface 508 of the substrate 510. The emitted laser beam 502 may has a wavelength ranging from about 400 nm to about 1,000 nm. The emitted laser beam 502 impinges on a location 512 of the surface 508. Depending on the curvature of the substrate 124 at the location 512, the emitted laser beam 502 may be reflected into different directions. When the substrate 124 has very little warpage at the location 512, a large portion of a reflected laser beam 506 can travel back to the transceiver head 510. The photodetector of the transceiver head 510 can detect an intensity of the received laser beam 506. As the warpage of the substrate 124 directly affects the amount of the reflected beam 506 that can reach the transceiver head 510, the controller 238 (shown in FIG. 2) can determine a curvature of the surface 508 based on the intensity of signals corresponding to the received reflected laser beam 506. When a plurality of the warp sensors 246 are installed, a warpage profile showing curvatures across the front surface 508 can be obtained.

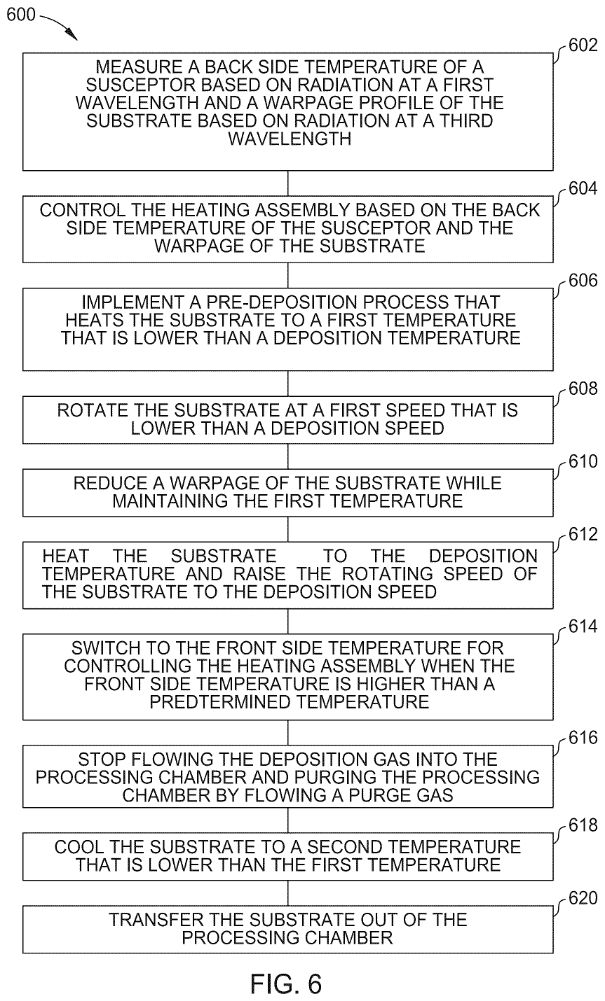

FIG. 6 illustrates a warpage control method 600 that can be practiced in a substrate processing chamber, according to an embodiment of the present disclosure. The processing chamber is capable of processing a SiC substrate at a ramp rate between 10° C./second to 100° C./second without causing unacceptable large warpage of the SiC substrate. The power of the heating lamps may be at least 600 W, 800 W, 1,000 W, or even higher. The warpage control method 600 starts with transferring a substrate from a transfer chamber to a substrate processing chamber. During the period when the substrate is being transferred, a purge gas, such as an inert gas or a hydrogen gas, may be flown into the processing chamber for protecting the substrate. Then, a heating assembly starts heating the substrate. The heating assembly includes a plurality of independently controllable heating zones.

At operation 602, the backside temperature of the susceptor is measured. As the substrate is supported by a susceptor, the backside temperature of the susceptor is measured by the thermal sensors disposed below the susceptor. The backside temperature is measured based on radiation at a first wavelength. In addition, a warpage profile of the substrate is measured by the warp sensor based on radiation at a third wavelength. The warpage profile may include a plurality of curvatures at different locations of the substrate as measured by the warp sensors.

At operation 604, the controller controls the heating assembly based on the backside temperature and the warpage profile of the substrate. The heating assembly is configured to evenly and rapidly heat up the substrate. The controller may adjust the power supplied to the heating assembly to control a temperature ramping up rate. The controller may adjust the power to a subset of heat lamps of the heating assembly to control the temperature of a local zone of the substrate or the susceptor. The controller may also adjust the waveforms of a power signal for the heating assembly, such as frequency, intensity, pulsing rate, pulsing period, and other parameters. In an example, the heating assembly is capable of heating the substrate between 10° C./second and 100° C./second. The temperature difference across the surface of the substrate is controlled to be no greater than 10° C., 5° C., or 1° C.

At operation 606, a pre-deposition process is implemented that heats the substrate to a first temperature that is lower than a deposition temperature. For example, the first temperature may be between about 600° C. and about 1,000° C., while the deposition temperature may be at least 1,500° C. or at least 1,800° C. During operation 606, the controller may control the heating assembly with an open-loop control algorithm.

At operation 608, the substrate is rotated by the susceptor at a first speed that is lower than a deposition speed. In an embodiment, the deposition speed may be as high as 2,000 rpm. The first speed may be at least 200 rpm or at least 500 rpm.

At operation 610, the controller controls the heating assembly to reduce a warpage of the substrate while the first temperature is maintained. The controller may implement a closed-loop control algorithm to achieve an optimized warpage profile. The heating assembly is controlled according to the temperature profile measured by the thermal sensors and the warpage profile measured by the warp sensors. As the heating assembly has a plurality of independently controllable heating zones, the controller can adjust the power of each heating zone to control the temperature of a local area, thus generating a uniform temperature profile and reducing the warpage. For example, when a location shows a lower temperature, the power of the heating zone underneath that location may be increased to raise the temperature. In an embodiment, the controller may additionally control the heating assembly to reduce a warpage of the substrate before the first temperature is reached, such as during a temperature ramp up period. The controller may implement an open-loop control method for controlling the heating assembly during a temperature ramp up period.

In an embodiment, the heating assembly determines a time-temperature trajectory of the substrate for consecutive time increments, referred to herein as time steps. The time steps are preferably of a short duration, for example on the order of about 0.1 sec to about 0.01 seconds or less. For a present given time step, each heating zone is heated to a desired temperature. And each thermal sensor measures the temperature of the substrate, and each warp sensor measures the curvature of the substrate. Measured temperatures and curvatures are provided to the controller, which uses a control algorithm to determine the power output for the lamps in each heating zone for the next time step.

A variety of temperature controlling algorithms are contemplated by the present disclosure for heating the substrate uniformly. In one example, a real-time adaptive control algorithm is used to control the heating of the substrate, wherein the properties of the substrate is measured at each time step to calculate the desired power input for the next step. In another example, an appropriate control algorithm is selected from a suite of several fixed control algorithms. A fixed control algorithm may require less computing power and may provide a faster response. The selection of the fixed control algorithm may be based on measured substrate properties, such as frontside emissivity of the substrate. In another example, several algorithms may be combined, in which a limited number of heating zones utilize an adaptive control algorithm and other heating zones are controlled by a fixed control algorithm, such as a binned algorithm.

The adaptive temperature controlling algorithm of the present disclosure may utilize the currently measured parameters of the substrate as inputs to determine the power of the heating zones of the next step. The currently measured parameters of the substrate include the warpage profile of the substrate, the temperature profile of the substrate, optical properties of the substrate, and the current power of the heating zones. A “binned” fixed control algorithm includes a number of different control algorithms have been optimized for different substrate properties and are stored, or binned in the controller according to the value of the substrate properties. For example, the fixed controlled algorithms may be binned according to a frontside emissivity of the substrate.

In an embodiment, the controller determines whether the warpage profile is acceptable based on the readings of the warp sensors. In an example, when one or more warp sensors measured a predetermined amount of the reflected laser beam, the controller determines that the warpage file is acceptable.

At operation 612, when the temperature profile or warpage profile meets predetermined criteria, the substrate's temperature is raised from the first temperature to a pre-clean temperature, which may be in the range of between 1400° C. to 1800° C. The pre-clean temperature may be maintained for a few seconds to a few minutes to remove any unwanted materials from a substrate. Then, the temperature is raised to the deposition temperature. The rotational speed of the susceptor is also raised to the deposition speed. In an embodiment, the temperature may be raised directly to the deposition temperature without maintaining the pre-clean temperature.

In an embodiment, the substrate is a SiC substrate, which is transparent and then becomes opaque above a threshold temperature around 1,200° C. When processing a SiC substrate during the operation 612, the control method activates the top thermal sensor to measure the topside temperature of the SiC substrate when the temperature is above about 1,200° C. The topside thermal sensors are configured to measure temperatures by measuring a blackbody emission of the substrate 124 at a second wavelength. In an embodiment, the first wave length used by the backside thermal sensor is longer than the second wavelength. In an example, the first wavelength is at least about 3 μm, such as about 5.2 μm. The second wavelength is between about 500 nm and about 3 μm. The control method also controls the heating assembly based on the warpage, the backside temperature, and the topside temperature.

At operation 614, the measurement of the topside temperatures is activated when the temperature is above a predetermined temperature, such as 1,200° C. The controller may use both the topside temperature and the backside temperature for control or switch to the topside temperature for controlling the heating assembly. As the topside thermal sensors have an emissivity correction system to account of deposited materials, the topside thermal sensors can more accurately measure the temperature than the back side thermal sensors. After the switching to the topside temperature is completed, a deposition gas is provided into the processing chamber for deposition. The processing chamber 200 is configured to deposit a SiC film on the substrate 124. The deposition gases for depositing a SiC film may include a silicon (Si) source gas, a carbon source gas, an additive gas, or any other suitable gas. The Si source gas may include monosilane, dichlorosilane, trichlorosilane, silicone tetrachloride, or any other suitable Si source gas. The carbon source gas may include propane, acetylene, ethylene, or any other suitable carbon source gas. The additive gas may include a hydrogen chloride gas or a dopant gas. The carrier gas may include a hydrogen (H2) gas or an inert gas, such as helium, argon, or other inert gas. The purge gas may include a hydrogen gas or an inert gas, helium, argon, or other inert gas.

In an embodiment, the controller utilizes both the topside temperature and the backside temperature during the deposition. The controller may give greater weight to the backside temperature for controlling deposition at edges of the substrate and may give greater weight to the topside temperature for controlling deposition at areas of the substrate other than the edges.

At the end of the deposition process, the flowing of the deposition gas into the processing chamber is stopped at operation 616. A purge gas, such as an inert gas, is flowed into the processing chamber to purge the deposition gas and prepare the processing chamber for a removal of the substrate.

At operation 618, the substrate is cooled to a second temperature that is lower than the first temperature. In an embodiment, the substrate can be cooled by flowing a purge gas along the backside of the substrate. The heating assembly is also configured to lower its temperature to assist the cooling of the substrate. The heating assembly not only has the output power reduced, but also circulates a heat transferring fluid, such as water, within a cooling channel inside the heating assembly for cooling. The second temperature may be between 800° C. to 1,200° C. Either the topside temperature or the backside temperature or both may be used to control the heating assembly.

At operation 620, the substrate is transferred out of the processing chamber once the second temperature is reached. An inert gas may be flowing as a protective gas when the substrate is transferred out of the processing chamber. In an embodiment, the susceptor supporting a SiC substrate is transferred out of the processing chamber together with the SiC substrate.

It is contemplated that one or more aspects disclosed herein may be combined. Moreover, it is contemplated that one or more aspects disclosed herein may include some or all of the aforementioned benefits. While the foregoing is directed to embodiments of the present disclosure, other and further embodiments of the disclosure may be devised without departing from the basic scope thereof, and the scope thereof is determined by the claims that follow.

What is claimed is:

1. A method of operating a substrate processing chamber, the method comprising:
heating a substrate supported by a susceptor by a heating assembly;
measuring a backside temperature of the susceptor;
measuring a warpage of the substrate; and
controlling the heating assembly based on the backside temperature and the warpage.

2. The method of claim 1, further comprising:
controlling, during a pre-deposition process before the backside temperature reaches a first temperature that is lower than a deposition temperature, the heating assembly based on the backside temperature and the warpage;
measuring a topside temperature of the substrate; and
controlling the heating assembly based on at least the topside temperature during a ramping up process to heat the substrate from the first temperature to the deposition temperature.

3. The method of claim 1, further comprising:
measuring a topside temperature of the substrate; and
controlling the heating assembly based on the backside temperature, the topside temperature, and the warpage.

4. The method of claim 3, wherein the backside temperature is measured based on radiation at a first wavelength, and the topside temperature is measured based on radiation at a second wavelength shorter than the first wavelength.

5. The method of claim 4, wherein the first wavelength is between about 3 μm and about 5.2 μm.

6. The method of claim 1 further comprising:
implementing a pre-deposition process that comprises:
heating the substrate to a first temperature that is lower than a deposition temperature; and
rotating the substrate at a first speed that is lower than a deposition speed.

7. The method of claim 6, further comprising:
reducing a warpage of the substrate while maintaining the first temperature, wherein reducing the warpage comprises controlling the heating assembly based on the backside temperature and the warpage.

8. The method of claim 7 further comprising:
heating the substrate from the first temperature to the deposition temperature; and
increasing a speed of rotating the substrate to the deposition speed.

9. The method of claim 8 further comprising:
measuring a topside temperature of the substrate;
switching to the topside temperature for controlling the heating assembly when the topside temperature is stable and/or has reached a threshold temperature; and
flowing a deposition gas into the substrate processing chamber.

10. The method of claim 9 further comprising:
stopping flowing the deposition gas into the substrate processing chamber;
purging the substrate processing chamber by flowing a purge gas;
cooling the substrate to a second temperature that is lower than the first temperature; and
transferring the substrate together with the susceptor out of the substrate processing chamber.

11. The method of claim 8, wherein the substrate is heated at a rate of no less than 40° C./second, and the first speed is between 200 RPM and 500 RPM.

12. A substrate processing system comprising:
a heating assembly including a plurality of heating lamps;
a first thermal sensor configured to measure a backside temperature of a susceptor supporting a substrate;
a warp sensor disposed above the heating assembly and configured to measure a warpage of the substrate; and
a controller to control the heating assembly based on the backside temperature and the warpage.

13. The substrate processing system of claim 12, wherein the backside temperature is measured based on radiation at a first wavelength being between about 3 μm and about 5.2 μm.

14. The substrate processing system of claim 12, wherein the heating assembly comprises a plurality of independently controllable heating zones.

15. The substrate processing system of claim 14, wherein the heating assembly comprises a structure made by an additive manufacturing process and comprising a plurality of reflectors surrounding the plurality of heating lamps, the structure further comprising a cooling channel surrounding the plurality of the reflectors.

16. The substrate processing system of claim 12, further comprising:
a second thermal sensor disposed above the heating assembly and configured to measure a topside temperature of the substrate; wherein the controller controls the heating assembly based on the backside temperature, the topside temperature, and the warpage.

17. The substrate processing system of claim 16, wherein the backside temperature is measured based on radiation at a first wavelength, and the topside temperature is measured based on radiation at a second wavelength shorter than the first wavelength.

18. The substrate processing system of claim 17, wherein the first wavelength is about 5.2 μm.

19. The substrate processing system of claim 16, wherein the heating assembly comprises a plurality of independently controllable heating zones.

20. The substrate processing system of claim 17, wherein the heating assembly comprises a structure made by an additive manufacturing process and comprising a plurality of reflectors surrounding the plurality of heating lamps, the structure further comprising a cooling channel surrounding the plurality of the reflectors.
